(19) United States
(12) Patent Application Publication
(10) Pub. No.: US 2014/0269107 A1
(43) Pub. Date: Sep. 18, 2014

(54) SEMICONDUCTOR DEVICE, SEMICONDUCTOR MEMORY DEVICE AND METHOD OF CONTROLLING THE SAME

(71) Applicant: Kabushiki Kaisha Toshiba, Minato-ku (JP)

(72) Inventors: Satoshi INOUE, Yokohama-shi (JP); Yuui SHIMIZU, Kawasaki-shi (JP)

(73) Assignee: Kabushiki Kaisha Toshiba, Minato-ku (JP)

(21) Appl. No.: 14/023,603

(22) Filed: Sep. 11, 2013

Related U.S. Application Data
(60) Provisional application No. 61/786,885, filed on Mar. 15, 2013.

(51) Int. Cl. G11C 7/10

(52) U.S. Cl. CPC G11C 7/1057
USPC 365/189.05

(57) ABSTRACT

A semiconductor memory device comprises an inner circuit, an output buffer circuit, an output buffer controlling circuit, and a chip operation temperature sensor. The output buffer circuit outputs data from the inner circuit via a data input/output pad. The output buffer controlling circuit controls a driving power of the output buffer circuit. The chip operation temperature sensor detects an operation temperature of a chip of the semiconductor device. The output buffer controlling circuit selects an impedance controlling condition from a plurality of the impedance controlling conditions according to the output signal of the chip operation temperature sensor and controls the output buffer circuit according to the selected impedance controlling condition.

### CROSS-REFERENCE TO RELATED APPLICATIONS

This application is based upon and claims the benefit of U. S. Provisional Patent Application No. 61/786,885, filed on Mar. 15, 2013, the entire contents of which are incorporated herein by reference.

### FIELD

The embodiments described herein relate to a semiconductor memory device and a method of testing the same.

### BACKGROUND

### Description of the Related Art

Recently, in a field of semiconductor devices, for example, NAND Flash memories, operation speeds of interfaces which inputs data sent from controller chips to memory chips and outputs data sent from the memory chips to the controller chips are more fastened. Furthermore, output resistances (Ron) of output buffers vary between systems in optimum values. Therefore, the output buffers are configured to have functions controlling the output resistances and are used with controlled output resistances according to environments. Additionally, according to the fastening of the operation speeds of the interfaces, amplitudes of signals between the semiconductor chips are decreased and a problem based on reflections of signals is occurred by impedance mismatching. In semiconductor chips which need such fast-operating interfaces, impedance matching circuits called “On Die Termination (ODT)” are equipped.

### BRIEF DESCRIPTION OF THE DRAWINGS

FIG. 1 is a block diagram showing a configuration of a semiconductor memory device according to a first embodiment.

FIG. 2 is a block diagram showing a configuration of apart of a data input/output buffer 2 according to the same embodiment.

FIG. 3 is a flowchart showing a reading method of the semiconductor memory device according to the same embodiment.

FIG. 4 is a schematic diagram showing a relationship between a change of an operation temperature and a waveform of an output signal from a semiconductor memory device according to prior arts.

FIG. 5 is a block diagram showing a structure of a part of a data input/output buffer 2′ of a semiconductor memory device according to a second embodiment.

FIG. 6 is a flowchart showing a writing method according to the second embodiment.

FIG. 7 is a block diagram showing a structure of a part of a data input/output buffer 2-3 of a semiconductor memory device according to a third embodiment.

FIG. 8 is a block diagram showing a structure of a part of a data input/output buffer 2-4 of a semiconductor memory device according to a fourth embodiment.

FIG. 9 is a block diagram showing a structure of a buffer circuit 25 of the data input/output buffer 2-4.

### DETAILED DESCRIPTION

A semiconductor memory device according to embodiments described below comprises an inner circuit, an output buffer circuit, an output buffer controlling circuit, and a chip operation temperature sensor. The output buffer circuit outputs data from the inner circuit via a data input/output pad. The output buffer controlling circuit controls a driving power of the output buffer circuit. The chip operation temperature sensor detects an operation temperature of a chip of the semiconductor device. The output buffer controlling circuit selects an impedance controlling condition from a plurality of the impedance controlling conditions according to the output signal of the chip operation temperature sensor and controls the output buffer circuit according to the selected impedance controlling condition.

Hereinafter, a semiconductor device, a semiconductor memory device and a method of controlling the semiconductor memory device according to embodiments are described with reference to the accompanying drawings.

### First Embodiment

[Configuration]

FIG. 1 is a block diagram of a semiconductor memory device according to a first embodiment. The semiconductor memory device comprises a memory body 1 storing data. The memory body 1 is configured by NAND-type flash memories, NOR-type flash memories, ReRAM or the like. Furthermore, the memory body 1 comprises a memory region 11 to which data are stored and ROM region 12 to which a plurality of impedance controlling conditions is stored.

A data input/output buffer 2 is connected to external host 3 via data pads Pd inputting input data and outputting output data. The data input/output buffer 2 receives writing data, receives erasing commands, outputs read data and receives address data and command data. The data input/output buffer 2 sends the writing data received from host 3 to the memory body 1 and outputs the read data read from the memory body 1 to the host 3. The address data supplied to the data input/output buffer 2 from the external host 3 is sent to the memory body 1 via an address resistor 4.

The commands supplied to the data input/output buffer 2 from the host 3 are sent to a command interface 5. The command interface 5 receives external controlling signals, verifies whether the received data is a command or an address, and if the input data is a command, receives the input data and sends the input data to a state machine 6.

The state machine 6 entirely manages the semiconductor memory device, receives commands sent from the host 3 via the command interface 5, and performs reading operation, writing operation, erasing operation, management of data input/output and so on.

The external host 3 may receive status information managed by the state machine 6 and may verify results of the operations. This status information can also be used to control the writing operation and the erasing operation.

A voltage-generating circuit 7 generates inner voltage from supplied voltage and supplies the inner voltage to each configurations of the semiconductor memory device. A chip operation temperature sensor 8 detects an operation temperature of a chip of the semiconductor memory device according to the embodiment and outputs the operation temperature of the chip to the data input/output buffer 2.

[the Data Input/Output Buffer 2]

A configuration of the data input/output buffer 2 according to the embodiment is described. When data is output from an off chip driver (OCD) of the data input/output buffer 2 to external of the semiconductor memory device, an output resistance (Ron) fluctuates due to the operation temperature of the chip. If an output-impedance of a data input/output node nio is not the same as an impedance of an external transmission line, errors can be generated. The data input/output buffer 2 according to the embodiment comprises the same number of output buffer circuits 21 and output buffer controlling circuits 22 as input/output nodes nio.

[The Output Buffer Circuit 21]

As shown in FIG. 2, the output buffer circuit 21 comprises a pull-up circuit 211 and a pull-down circuit 212 controlling the output resistance (Ron). The pull-up circuit 211 comprises a plurality of variable-resistance units VRU1 to VRUn connected in parallel between a supplied-voltage-supplying node VccQ and the data input/output node nio. A variable resistance unit VRUk (“k” is an integer number from 1 to n) is composed from 2^{k-1} resistance-controlling P-channel transistors connected in parallel. The resistance-controlling P-channel transistors respectively have drain terminals connected to the data input/output node nio and source terminals connected to the supplied-voltage-supplying node VccQ. The pull-up controlling circuit 211 inputs output resistance data composed from n-bits binary data from the buffer controlling circuit 22 as the impedance controlling condition. Gate electrodes of the 2^{k-1} resistance-controlling P-channel transistors composing the variable resistance unit URUk commonly input a k-ordered datum of the output resistance data. Additionally, the resistance-controlling P-channel transistors included by the pull-up circuit 211 are formed so that channel widths, channel lengths and so on are the same as each other. Therefore, the pull-up circuit 211 is able to set a pull-up resistance between the supplied-voltage-supplying node VccQ and the data input/output node nio to certain resistance value selected from 2ⁿ resistance values according to the output resistance data.

Similar to the pull-up circuit 211, the pull-down circuit 212 is able to control a resistance value between the data input/output node nio and the ground terminal Vss by controlling conductive states of plurality of transistors. The pull-down circuit 212 comprises a plurality of variable-resistance unit VDU1 to VDUn connected in parallel between the data input/output node nio and the ground terminal Vss. A variable-resistance unit VDUk (“k” is a integer number from 1 to n) is composed from 2^{k-1} resistance-controlling N-channel transistors connected in parallel. The resistance-controlling N-channel transistors respectively have drain terminals connected to the data input/output node nio, source terminals connected to the ground terminal Vss and gate terminals to which k-ordered datum of the output resistance data is commonly inputted. Additionally, the resistance-controlling N-channel transistors included by the pull-down circuit 212 are formed so that channel widths, channel lengths and so on of the resistance-controlling N-channel transistors are the same as each other. Therefore, the pull-down circuit 212 is able to set a pull-down resistance between the data input/output node nio and the ground terminal Vss to certain resistance value selected from 2ⁿ resistance values according to the output resistance data.

[The Output Buffer Controlling Circuit 22]

The output buffer controlling circuit 22 comprises pull-up output buffer controlling circuit 221 outputting the output resistance data to the pull-up circuit 211 and the pull-down output buffer controlling circuit 222 outputting the output data to the pull-down circuit 212. The pull-up output buffer controlling circuit 221, according to an input of the impedance controlling condition selecting command from the state machine 6, compares temperature data output from the chip operation temperature sensor 8 with a temperature data memorized in the ROM region of the memory body 1, selects an appropriate output resistance data from a plurality of output resistance data and outputs the appropriate output resistance data to the pull-up circuit 211. The plurality of the output resistance data can be previously latched to the resistor and so on. Furthermore, the pull-down output buffer controlling circuit 222 is composed similarly to the pull-up output buffer controlling circuit 221, selects the output resistance data corresponding to the temperature range to which the chip belongs at the timing of an input of the impedance controlling condition selecting command and outputs the selected output resistance data to the pull-down circuit 212.

[The Chip Operation Temperature Sensor 8]

The chip operation temperature sensor 8 according to the embodiment divides the operation temperature of the chip into the two or more temperature ranges and shows the temperature range to which the operation temperature of the chip belongs by outputting an output signal. For example, in this embodiment, it is decided that the operation temperature of the chip belongs to a temperature range A if the operation temperature of the chip is lower than −40 degrees, it is decided that the operation temperature of the chip belongs to a temperature range B if the operation temperature of the chip is −40 degrees to 85 degrees and it is decided that the operation temperature of the chip belongs to a temperature range C if the operation temperature of the chip is higher than 85 degrees. Furthermore, the chip operation temperature sensor 8 outputs a temperature data A, a temperature data B or a temperature data C respectively according to the temperature range A, the temperature range B and the temperature range C.

[Reading operation]

A reading operation of the semiconductor memory device is described with reference to FIG. 3. In a step S11, the output resistance data is selected. In this embodiment, the state machine 6 detects an input of reading command sent to the command interface 5 from the host 3 and outputs the impedance controlling condition selecting command to the output buffer controlling circuit 22. The pull-up output controlling circuit 221 and the pull-down output controlling circuit 222 detects the operation temperature of the chip at the timing of the input of the impedance controlling condition selecting command from the temperature data, select the output resistance data corresponding to the input temperature data and latch the selected output resistance data.

In a step S12, data is read from the memory region 11 of the memory body 1. For example, if the memory body 1 is composed from NAND type Flash memory, read voltage is applied to a word line and data latched to memory cells are determined from currents flowing to bit lines.

In a step S13, the output impedance of the data input/output node nio is controlled according to the output resistance data selected in the step S11 and the data read from the memory body 1 is output. If read data is “1”, the output of the data is performed by controlling the pull-up circuit 211 according to the output resistance data selected by the pull-up resistance controlling circuit 221 and pulling up the voltage of the data input/output node nio. Additionally, gate voltage of the resistance controlling N-channel transistors composing the pull-down circuit 212 is controlled to the ground voltage and data input/output node nio and the ground node are electrically isolated from each other. If read data is “0”, the output of the data is performed by controlling the pull-down circuit 212 according to the output resistance data selected by the pull-down resistance controlling circuit 222 and pulling down the voltage of the data input/output node nio. Additionally, gate voltage of the resistance controlling P-channel transistors composing the pull-up circuit 211 is controlled to the supplied voltage or the like and data input/output node nio and supplied voltage supplying node VccQ are electrically isolated from each other. Note that switching elements or the like can be included by data input/output buffer 2 and the electrical isolation of the input/output nodes nio and other structures (the ground nodes and the supplied voltage supplying nodes) can also be realized by the switching elements and so on.

In a step S14, whether if all data read from the memory body 1 have been output or not is confirmed, the output of the data is continuously performed if all the data have not been output and the reading operation is finished if all the data have been output already. That is, while all the data read in one reading operation are being output, the pull-up circuit 211 is controlled according to the output resistance data selected in the step S11 and the pull-down circuit 212 is controlled according to the output resistance data selected in the step S11.

[Effect]

The output impedance of the data input/output node nio can be controlled according to specs of semiconductor integrated circuits, demands of users and so on. The output impedance can be controlled by controlling the output resistance data. FIG. 4(a) shows a waveform of a signal output from the data input/output node nio if the output impedance is appropriately controlled. If the operation temperature of the chip is less than a specific temperature, as shown in FIG. 4(b), because a driving power of the output buffer circuit 21 becomes too strong, ringing appears to waveform of the output signal of the data input/output buffer 2 and it can arises errors. On the other hand, if the operation temperature of the chip is higher than a specific temperature, as shown in FIG. 4(c), because the driving power of the output buffer circuit 21 becomes too weak, the waveform of the output signal of the data input/output buffer 2 is rounded and errors can be occurred.

In this embodiment, the operation temperature of the chip is detected by the chip operation temperature sensor 8, the appropriate output resistance data is selected according to the output signal of the chip operation temperature sensor 8 and the output impedance of the data input/output node nio is controlled using the selected output resistance data. Therefore, the ringing and the rounding of the waveform of the output signal are suppressed and occurrences of the errors can be suppressed.

Additionally, in this embodiment, the operation temperature of the chip is divided into the two or more temperature ranges and the output signal corresponding to the temperature range to which the operation temperature of the chip belongs is output. Accordingly, fast process can be realized. Furthermore, in this embodiment, because the output resistance data is selected according to the input of the reading command, the output impedance does not fluctuate while the read data is output.

### Second Embodiment

[Overall Configuration]

Next, a semiconductor memory device according to the second embodiment is described. In the first embodiment, a method of controlling the output impedance of the data input/output node nio is described. In contrast, in the second embodiment, a semiconductor memory device comprising a data input/output buffer 2′ having an On Die Termination (ODT) function which controls a terminating resistance of the data pads Pd is described. The data input/output buffer 2′ according to the embodiment comprises ODT circuits 23 and ODT controlling circuits 24 with respect to the input/output nodes nio.

The CDT circuit 23, as shown in FIG. 5, comprises pull-up circuit 231 and pull-down circuit 232 setting an input impedance of the input/output nodes nio. Although the pull-up circuit 231 is composed almost the same as the pull-up circuit 211 according to the first embodiment, the pull-up circuit 231 according to this embodiment comprises a plurality of resistive elements R1 to Rn respectively connected to the plurality of variable resistance units VRU1 to VRUn serially. A resistance value of a resistive element Rk (“k” is an integer number less than n−1) is twice as a resistance value of a resistive element Rk−1. Because the pull-up circuit 231 according to the embodiment has the resistive elements R1 to Rk, current value changes according to voltage value more linearly than the pull-up circuit 211 according to the first embodiment. Therefore, the pull-up resistance of the input/output node can be nicely controlled. Likewise, the pull-down circuit 232 according to this embodiment comprises a plurality of resistive elements R1 to Rn respectively connected to the plurality of variable resistance units VDU1 to VDUn serially. However, it is possible to compose the pull-up circuit 231 and the pull-circuit 232 without the resistive elements R1 to Rn similarly to the pull-up circuit 211 and the pull-down circuit 212 according to the first embodiment. Additionally, the pull-up circuit 211 and the pull-down circuit 212 according to the first embodiment may comprise the resistive elements R1 to Rn similarly to the second embodiment.

The ODT controlling circuit 24 comprises a pull-up impedance controlling circuit (pull-up terminating resistance controlling circuit) 241 outputting an impedance data to the pull-up circuit 231 and a pull-down impedance controlling circuit (pull-down terminating resistance controlling circuit) 242 outputting the impedance data to the pull-down circuit 232. The pull-up impedance controlling circuit 241, according to an input of the impedance controlling condition selecting command from the state machine 6, compares the temperature data output from the chip operation temperature sensor 8 with a temperature data memorized in the ROM 12 region of the memory body 1, selects an appropriate input impedance data from a plurality of input impedance data and outputs the appropriate input impedance data to the pull-up circuit 231. The plurality of the input impedance data can be previously latched to the resistor and so on. Furthermore, the pull-down impedance controlling circuit 242 is composed similarly to the pull-up impedance controlling circuit 241, selects the input impedance data corresponding to the temperature range to which the chip belongs at the timing of the input of the impedance controlling condition selecting command and outputs the selected input impedance data to the pull-down circuit 232.

[Writing Operation]

Next, a writing operation of the semiconductor memory device according to the embodiment is described with reference to FIG. 6. In a step S21, the input impedance data is selected. That is, the state machine 6 detects an input of a read command from the host 3 and outputs the impedance controlling condition selecting command to the ODT controlling circuit 24. The pull-up impedance controlling circuit 241 and the pull-down impedance controlling circuit 242 detect the temperature range to which the chip belongs at the timing of the input of the impedance controlling condition selecting command, select an input impedance data according to the detected temperature range and latch the selected input impedance data.

In a step S22, the input impedance of the data input/output node nio is controlled using the selected input impedance data in the step S21, and writing data is input via the data input/output node nio. While the writing data is being input, the ODT controlling circuit 24 controls the pull-up circuit 231 and the pull-down circuit 232 to conducting states and controls the input impedance of the data input/output node nio. Note that it is possible to control only one of the pull-up circuit 231 and the pull-down circuit 232 according to circumstances.

In a step S23, whether the input of the writing data is finished or not is confirmed. If the input of the writing data is finished, data writing to the memory body 1 is started (step S24). If the input of the writing data is not finished, the input of the writing data is continuously performed. Accordingly, while the writing data are being input to the semiconductor memory device in one writing operation, the pull-up circuit 231 and the pull-down circuit 232 are controlled according to the input impedance data selected in the step S21, respectively.

In the step S24, the input writing data is written to the memory region 11 of the memory body 1. For example, if the memory body 1 is composed by NAND-type flash memories, the input writing data is written by controlling voltages of word lines and bit lines according to the writing data and accumulating electrical charge to floating gates of memory cells. Additionally, a verify operation or a control of writing voltage, writing time (pulse width) or the like may be applied.

### Third Embodiment

Next, a semiconductor memory device according to a third embodiment is described. Although the semiconductor memory device according to the third embodiment is composed basically the same as the semiconductor memory device according to the first embodiment, as shown in FIG. 7, a data input/output buffer 2-3 according to the third embodiment comprises the output buffer circuit 21 and the output buffer controlling circuit 22 according to the first embodiment and the ODT circuit 23 and the ODT controlling circuit 24 according to the second embodiment with respect to the input/output nodes nio. In this embodiment, because the output buffer controlling circuit 22 and the ODT controlling circuit 24 are independently composed, for example, the input impedance data and the output resistance data can be respectively set in order to control the input impedance and the output resistance of the input/output node nio independently from each other. Therefore, the input/output impedance of the input/output node nio can be precisely controlled.

### Fourth Embodiment

Next, a semiconductor memory device according to fourth embodiment is described. A data input/output buffer 2-4 according to the embodiment is composed basically the same as the semiconductor memory device according to the first embodiment, however, as shown in FIG. 8, comprises the output buffer circuit 21 according to the first embodiment, the ODT circuit 23 according to the second embodiment and a buffer circuit controlling circuit 25 controlling the output buffer circuit 21 and the ODT circuit 23 with respect to the input/output nodes nio. In this embodiment, functions of the output buffer controlling circuit 22 according to the first embodiment and the ODT controlling circuit 24 according to the second embodiment are realized by the buffer circuit controlling circuit. Hence, circuit size can be suppressed relative to the third embodiment.

The buffer circuit controlling circuit 25, as shown in FIG. 9, comprises a pull-up buffer controlling circuit 251 and a pull-down buffer controlling circuit 252. The pull-up buffer controlling circuit 251, according to the input of the impedance controlling condition selecting command from the state machine 6, compares the temperature data output from the chip operation temperature sensor 8 with a temperature data memorized in the ROM region 12 of the memory body 1, selects the appropriate input/output resistance data from the plurality of input/output resistance data and outputs the appropriate input/output resistance data to the pull-up circuit 211 and the pull-up circuit 231. The plurality of the input/output resistance data can be previously latched to the resistor and so on. Furthermore, the pull-down buffer controlling circuit 252 is composed similarly to the pull-up buffer controlling circuit 251, selects the input/output resistance data corresponding to the temperature range to which the chip belongs at the timing of an input of the impedance controlling condition selecting command and outputs the selected input/output resistance data to the pull-down circuit 212 and the pull-down circuit 232.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device, comprising:
an inner circuit;
an output buffer circuit outputting data from the inner circuit via a data input/output pad;
an output buffer controlling circuit controlling a driving power of the output buffer circuit; and
a chip operation temperature sensor detecting an operation temperature of a chip of the semiconductor device, wherein
the output buffer controlling circuit selects an impedance controlling condition from a plurality of the impedance controlling conditions according to the output signal of the chip operation temperature sensor and controls the output buffer circuit according to the selected impedance controlling condition.

2. The semiconductor device according to claim 1, wherein
the chip operation temperature sensor divides the operation temperature of the chip into the two or more temperature ranges and shows the temperature range to which the operation temperature of the chip belongs by outputting an output signal, and
the output buffer controlling circuit controls the driving power of the output buffer circuit according to the impedance controlling condition corresponding to the temperature range shown by the chip operation temperature sensor.

3. The semiconductor device according to claim 2, wherein
the output buffer circuit comprises a plurality of resistance-controlling P-channel transistors connected in parallel between a supplied-voltage-supplying pad and the data input/output pad and a plurality of resistance-controlling N-channel transistors connected in parallel between the data input/output pad and a ground-voltage-supplying pad,
the driving power of the output buffer circuit is controlled by controlling conduction states of the plurality of the resistance-controlling P-channel transistors and the plurality of the resistance-controlling N-channel transistors according to output resistance data as the impedance controlling condition, and
the output buffer controlling circuit controls at least one of the conduction states of the resistance-controlling P-channel transistors and the conduction states of the resistance-controlling N-channel transistors according to the output resistance data corresponding to the temperature range shown by the chip operation temperature sensor.

4. The semiconductor device according to the claim 3, wherein
the output buffer controlling circuit selects the output resistance data corresponding to the output signal of the chip operation temperature sensor according to an output command and controls the driving power of the output buffer circuit according to the selected output resistance data.

5. The semiconductor device according to the claim 1, further comprising:
an on die termination circuit controlling a termination resistance of the input/output pad; and
an on die termination controlling circuit controlling a driving power of the on die termination circuit, wherein
the on die termination controlling circuit selects one impedance controlling condition from the plurality of the impedance controlling conditions according to the output signal of the chip operation temperature sensor and controls the on die termination circuit according to the selected impedance controlling condition.

6. The semiconductor device according to claim 5, wherein
the chip operation temperature sensor divides the operation temperature of the chip into the two or more temperature ranges and shows the temperature range to which the operation temperature of the chip belongs by outputting an output signal, and
the on die termination controlling circuit controls the driving power of the on die termination circuit according to the one impedance controlling condition corresponding to the temperature range shown by the chip operation temperature sensor.

7. The semiconductor device according to claim 6, wherein
the on die termination circuit comprises:
a plurality of resistance-controlling P-channel transistors connected in parallel between a supplied-voltage-supplying pad and the data input/output pad;
a plurality of resistance-controlling N-channel transistors connected in parallel between the data input/output pad and a ground-voltage-supplying pad;
a plurality of first resistive elements respectively forming a plurality of current paths having different resistance values from each other between the supplied-voltage-supplying pads and the data input/output pads by being connected to the plurality of the resistance-controlling P-channel transistors in serial; and
a plurality of second resistive elements respectively forming a plurality of current paths having different resistance values from each other between the data input/output pads and a ground-voltage-supplying pad by being connected to the plurality of the resistance-controlling N-channel transistors in serial,
the driving power of the on die termination circuit is controlled by controlling conduction states of the plurality of the resistance-controlling P-channel transistors and the plurality of the resistance-controlling N-channel transistors according to input impedance data as the impedance controlling condition, and
the on die termination controlling circuit controls at least one of the conduction states of the resistance-controlling P-channel transistors and the conduction states of the resistance-controlling N-channel transistors according to the input impedance data corresponding to the temperature range shown by the output signal output from the chip operation temperature sensor.

8. The semiconductor device according to the claim 7, wherein
the on die termination controlling circuit selects the input impedance data corresponding to the output signal of the chip operation temperature sensor according to an input command and controls the driving power of the on die termination circuit according to the selected input impedance data.

9. A semiconductor memory device, comprising:
a memory body memorizing data;
an output buffer circuit outputting data from the memory body via a data input/output pad;
an on die termination circuit controlling a termination resistance of the input/output pad;
a buffer controlling circuit controlling a driving power of the output buffer circuit and controlling a driving power of the on die termination circuit; and
a chip operation temperature sensor detecting an operation temperature of a chip of the semiconductor memory device, wherein
the buffer controlling circuit selects an impedance controlling condition from a plurality of the impedance controlling conditions according to the output signal of the chip operation temperature sensor and controls the driving powers of the output buffer circuit and the on die termination circuit according to the selected impedance controlling condition.

10. The semiconductor memory device according to claim 9, wherein
the chip operation temperature sensor divides the operation temperature of the chip into the two or more temperature ranges and shows the temperature range to which the operation temperature of the chip belongs by outputting an output signal, and
the buffer controlling circuit controls the driving power of the output buffer circuit and the driving power of the on die termination circuit according to the impedance controlling condition corresponding to the temperature range shown by the chip operation temperature sensor.

11. The semiconductor memory device according to claim 10, wherein
the output buffer circuit comprises a plurality of resistance-controlling P-channel transistors connected in parallel between a supplied-voltage-supplying pad and the data input/output pad and a plurality of resistance-controlling N-channel transistors connected in parallel between the data input/output pad and a ground-voltage-supplying pad,
the driving power of the output buffer circuit is controlled by controlling conduction states of the plurality of the resistance-controlling P-channel transistors and the plurality of the resistance-controlling N-channel transistors according to output resistance data as the impedance controlling condition,
the on die termination circuit comprises:
a plurality of resistance-controlling P-channel transistors connected in parallel between the supplied-voltage-supplying pad and the data input/output pad;
a plurality of resistance-controlling N-channel transistors connected in parallel between the data input/output pad and the ground-voltage-supplying pad;
a plurality of first resistive elements respectively forming a plurality of current paths having different resistance values from each other between the supplied-voltage-supplying pads and the data input/output pads by being connected to the plurality of the resistance-controlling P-channel transistors in serial; and
a plurality of second resistive elements respectively forming a plurality of current paths having different resistance values from each other between the data input/output pads and the ground-voltage-supplying pad by being connected to the plurality of the resistance-controlling N-channel transistors in serial,
the driving power of the on die termination circuit is controlled by controlling conduction states of the plurality of the resistance-controlling P-channel transistors and the plurality of the resistance-controlling N-channel transistors according to input impedance data as the impedance controlling condition, and
the buffer controlling circuit comprises:
an output buffer controlling circuit controlling the output buffer circuit according to the output resistance data corresponding to the temperature range shown by the chip operation temperature sensor; and
an on die termination controlling circuit controlling the on die termination circuit according to the input impedance data corresponding to the temperature range shown by the chip operation temperature sensor.

12. The semiconductor memory device according to the claim 11, wherein
the output buffer controlling circuit selects the output resistance data corresponding to the output signal of the chip operation temperature sensor according to a read command and controls the driving power of the output buffer circuit according to the selected output resistance data.

13. The semiconductor memory device according to the claim 11, wherein
the on die termination controlling circuit selects the impedance controlling condition corresponding to the output signal of the chip operation temperature sensor according to a write command and controls the driving power of the on die termination circuit according to the selected impedance controlling condition.

14. The semiconductor memory device according to claim 10, wherein
the output buffer circuit comprises a plurality of resistance-controlling P-channel transistors connected in parallel between a supplied-voltage-supplying pad and the data input/output pad and a plurality of resistance-controlling N-channel transistors connected in parallel between the data input/output pad and a ground-voltage-supplying pad,
the driving power of the output buffer circuit is controlled by controlling conduction states of the plurality of the resistance-controlling P-channel transistors and the plurality of the resistance-controlling N-channel transistors according to output resistance data as the impedance controlling condition,
the on die termination circuit comprises:
a plurality of resistance-controlling P-channel transistors connected in parallel between the supplied-voltage-supplying pad and the data input/output pad;
a plurality of resistance-controlling N-channel transistors connected in parallel between the data input/output pad and the ground-voltage-supplying pad;
a plurality of first resistive elements respectively forming a plurality of current paths having different resistance values from each other between the supplied-voltage-supplying pads and the data input/output pads by being connected to the plurality of the resistance-controlling P-channel transistors in serial; and
a plurality of second resistive elements respectively forming a plurality of current paths having different resistance values from each other between the data input/output pads and a ground-voltage-supplying pad by being connected to the plurality of the resistance-controlling N-channel transistors in serial,
the driving power of the on die termination circuit is controlled by controlling conduction states of the plurality of the resistance-controlling P-channel transistors and the plurality of the resistance-controlling N-channel transistors according to input impedance data as the impedance controlling condition, and
the buffer controlling circuit selects the impedance controlling condition corresponding to the temperature range shown by the chip operation temperature sensor as the output resistance data and the input impedance data and controls the driving powers of the output buffer circuit and the on die termination circuit according to the selected impedance controlling condition.

15. The semiconductor memory device according to the claim 14, wherein
the buffer controlling circuit selects the impedance controlling condition corresponding to the output signal of the chip operation temperature sensor according to a read command and controls the driving power of the output buffer circuit according to the impedance controlling condition.

16. The semiconductor memory device according to the claim 14, wherein
the buffer controlling circuit selects the impedance controlling condition corresponding to the output signal of the chip operation temperature sensor according to a write command and controls the driving power of the on die termination circuit according to the selected impedance controlling condition.

17. A method of controlling a semiconductor memory device controlling a driving power of an output buffer circuit outputting data from a memory body via a data input/output pad by an output buffer controlling circuit,
detecting an operation temperature of a chip of the semiconductor memory device by a chip operation temperature sensor, and
by the output buffer controlling circuit, selecting an impedance controlling condition from a plurality of the impedance controlling conditions according to an output signal of the chip operation temperature sensor and controlling the driving power of the output buffer circuit according to the selected impedance controlling condition.

18. The method of controlling the semiconductor memory device according to claim 17, wherein
the chip operation temperature sensor divides the operation temperature of the chip into two or more temperature ranges,
the plurality of the impedance controlling conditions corresponds to the two or more temperature ranges, and
the output buffer controlling circuit controls the driving power of the output buffer circuit according to the impedance controlling condition corresponding to the temperature range to which the operation temperature of the chip belongs.

19. The method of controlling the semiconductor memory device according to the claim 18, wherein
the output buffer controlling circuit selects the output resistance data corresponding to the output signal of the chip operation temperature sensor according to a read command as the impedance controlling condition and controls the driving power of the output buffer circuit according to the selected output resistance data.

20. The method of controlling the semiconductor memory device according to the claim 18, wherein
the semiconductor memory device further comprises:
an on die termination circuit controlling a termination resistance of the input/output pad; and
an on die termination controlling circuit controlling a driving power of the on die termination circuit, and
the on die termination controlling circuit controls at least one of conduction states of a plurality of a resistance-controlling P-channel transistors included by the on die termination circuit and conduction states of a plurality of resistance-controlling N-channel transistors included by the on die termination circuit according to the input impedance data corresponding to the temperature range shown by the output signal output from the chip operation temperature sensor.
